(19) United States
(12) Patent Application Publication
(10) Pub. No.: US 2003/0104648 A1
(43) Pub. Date: Jun. 5, 2003

(54) Micromechanical component and method of manufacturing a micromechanical component

(76) Inventors: Joachim Rudhard, Leinfelden-Echterdingen (DE); Stefan Pinter, Reutlingen (DE); Frank Fischer, Gomaringen (DE); Franz Laermer, Weil Der Stadt (DE); Arnold Rump, Munchen (DE)

Correspondence Address: KENYON & KENYON, ONE BROADWAY, NEW YORK, NY, 10004, US

(21) Appl. No.: 10/175,982

(22) Filed: Jun. 19, 2002

Related U.S. Application Data
(63) Continuation of application No. 09/982,055, filed on Oct. 17, 2001.

(30) Foreign Application Priority Data
Oct. 17, 2000 (DE) 100 51 315.8

(51) Int. Cl. H01L 21/302

(52) U.S. Cl. 438/50; 73/514.35

(57) ABSTRACT

A micromechanical component is described, in particular an acceleration sensor or a rotational speed sensor having functional components which are movably suspended over a substrate, opposite surfaces of the functional components being movable toward one another. The opposite surfaces of the functional components are at least partially coated with a conductive film.

### FIELD OF THE INVENTION

The present invention relates to a micromechanical component, in particular an acceleration sensor or a rotational speed sensor, and a corresponding manufacturing method.

Although it can be applied to any micromechanical components and structures, in particular to sensors and actuators, the present invention and the underlying problem are elucidated with reference to a micromechanical acceleration sensor that can be manufactured using silicon surface micromachining technology.

### BACKGROUND INFORMATION

Acceleration sensors, in particular micromechanical acceleration sensors manufactured using surface or volume micromachining technology have an increasing market share in the automotive equipment industry and are increasingly replacing the piezoelectric acceleration sensors customarily used to date.

The known micromechanical acceleration sensors normally operate so that the flexibly mounted seismic mass device, which can be deflected in at least one direction by an external acceleration, on deflection causes a change in the capacitance of a differential capacitor device which is connected to it; this change in capacitance is a measure of the acceleration.

At the time of the deflection, the combs of the differential capacitor device may occasionally contact one another and remain stuck together. It must also be ensured that the movable component parts do not contact one another, since the smallest adhesion or attraction forces of less than 5 μN are sufficient to result in permanent deflection. In particular for low-g sensors, adhesion is a problem, since the restoring forces of the springs are small.

This phenomenon of solid adhesion in micromechanical components is generally referred to in the literature as “stiction.” “Stiction” is the tendency of two solid surfaces in mechanical contact with one another to stick together. An overview of the current state of discussions is given in R. Maboudian, R. T. Howe; Critical Review: Adhesion in surface micromechanical structures; J. Vac. Sci. Technol. B 15(1), Jan./Feb. 1, 1997, as well as in K. Komvopoulos; Surface Engineering and Microtribology for Microelectromechanical Systems; Wear 200(1996), 305-327.

Stiction basically means a surface effect resulting from the buildup of van der Waals and capillary forces, as well as from electrostatic interaction, and the formation of solid and hydrogen bridges.

Various methods for reducing this solid adhesion are proposed in the literature, in which

a) the surfaces are chemically stabilized by passivation layers (e.g. self-assembling monolayers),

a) the surfaces are hardened by coating (e.g. diamond-like carbons) or

c) the surface topography (contact surfaces, surface roughness) is optimized.

The ongoing discussion in the literature regarding electrostatic forces concerns such charges built into surface layers (e.g., in oxides), or conducted onto such surfaces from the outside. Worldwide research and development activities to date have focused on the mechanical and chemical properties of the surfaces. The electronic characteristics of the materials used have not been discussed.

The electronic properties, in particular the properties of surface states and deep fault locations in silicon have been discussed in detail in the literature concerning microelectronic components, for example, in S. M. Sze, Physics of Semiconductor Devices, 2^{nd} Edition, Wiley & Sons, N.Y. 1986. However, they have not been taken into consideration in discussing micromechanical systems.

The underlying known process sequence of surface micromachining technology for the manufacture of acceleration sensors and rotational speed sensors is described, for example, by Offenberg et al. in Acceleration Sensor in Surface Micromachining for Airbag Applications with High Signal/Noise Ratio; Sensors and Actuators, 1996, 35. The material used in which the mechanically movable elements are structured is highly phosphorus-doped polycrystalline silicon. Previous measures for reducing adhesion include surface coating with CVD oxide, resilient stops, and research concerning the shape of the contact surfaces.

The disadvantage of the known components is that the semiconductor and electrical properties of the basic materials used have been neglected in the previous discussions on stiction.

### SUMMARY OF THE INVENTION

The micromechanical component according to the present invention and the corresponding manufacturing method have the advantage that stiction can be prevented.

The basic idea of the present invention is that opposite surfaces of the functional components that are movable toward one another are at least partially coated with a conductive film. In metal plating a side wall, an electrically conductive connection is established between the semiconductor material and the metal film applied. In particular, for the differential capacitor structures that are known per se, a metal is expediently applied to the lateral surfaces of the capacitive elements in the component structure. Charge carriers on the electrode surfaces and near the semiconductor surface are quickly removed via this conductive layer and can recombine. Thus the long-lasting and far-reaching attraction force between these charges, and thus the tendency to electrostatic adhesion, can be reduced.

The present invention is based on the knowledge that a strong electrostatic interaction may occur between the movable elements due to the ionization of the fault locations or the formation of surface charges in the process or during operation of the components. This interaction between structures that are not in mechanical contact is taken into account in addition to the surface forces arising on mechanical contact.

The present invention allows charges on the functional component surfaces to be eliminated during the manufacture of micromechanical structures. The conductive coating can locally equalize and quickly recombine charges.

One particular advantage of the method is the possibility of integrating the conductive layer into the process known from the related art for manufacturing the micromechanical sensor by adding side wall metal plating to the previous process sequence. The side wall metal plating process module used has a deposition and a subsequent back etching step, both of which can be performed in the same system with a short process time and high reproducibility. In this method, short-circuits are avoided despite the use of conductive coating materials. The vertical stress gradient is also not modified.

According to a preferred refinement, the conductive film is a metal film containing, in particular, aluminum, an alloy based on AlSi and AlSiCu, nickel, or a NiSi alloy.

According to another preferred refinement, the surfaces of the functional components opposite one another are basically vertical side walls of trenches.

According to another preferred refinement, the upper area of the side walls have projections. They are used as shading elements.

According to another preferred refinement, the substrate is a silicon substrate on which a sacrificial oxide layer is provided, and the functional layer is a polysilicon layer provided on the sacrificial layer.

According to another preferred refinement, the conductive film is removed in the horizontal areas using an anisotropic physical etching method. Thus, a homogeneous film can be produced on the side walls.

According to another preferred refinement, some areas of the sacrificial layer are etched as the conductive film is removed in the horizontal areas.

According to another preferred refinement, annealing is performed to improve the electrical contact properties between the functional layer and the conductive film. This improves recombinability.

### BRIEF DESCRIPTION OF THE DRAWINGS

FIG. 1 schematically shows a first illustration of the manufacturing process for an acceleration sensor according to a first embodiment of the present invention in a cross-section.

FIG. 2 schematically shows a second illustration of the manufacturing process for the acceleration sensor according to the first embodiment of the present invention in a cross-section.

FIG. 3 schematically shows a third illustration of the manufacturing process for the acceleration sensor according to the first embodiment of the present invention in a cross-section.

FIG. 4 schematically shows a fourth illustration of the manufacturing process for the acceleration sensor according to the first embodiment of the present invention in a cross-section.

FIG. 5 schematically shows a fifth illustration of the manufacturing process for the acceleration sensor according to the first embodiment of the present invention in a cross-section.

FIG. 6 schematically shows a sixth illustration of the manufacturing process for the acceleration sensor according to the first embodiment of the present invention in a cross-section.

FIG. 7 schematically shows a first illustration of the manufacturing process for an acceleration sensor according to a second embodiment of the present invention in a cross-section.

FIG. 8 schematically shows a second illustration of the manufacturing process for the acceleration sensor according to the second embodiment of the present invention in a cross-section.

FIG. 9 schematically shows a third illustration of the manufacturing process for the acceleration sensor according to the second embodiment of the present invention in a cross-section.

FIG. 10 schematically shows a fourth illustration of the manufacturing process for the acceleration sensor according to the second embodiment of the present invention in a cross-section.

FIG. 11 schematically shows a fifth illustration of the manufacturing process for the acceleration sensor according to the second embodiment of the present invention in a cross-section.

FIG. 12 schematically shows the removal and recombination of charges on the electrode surfaces in the present invention in a cross-section.

### DETAILED DESCRIPTION

In the Figures identical symbols denote identical or functionally equivalent components.

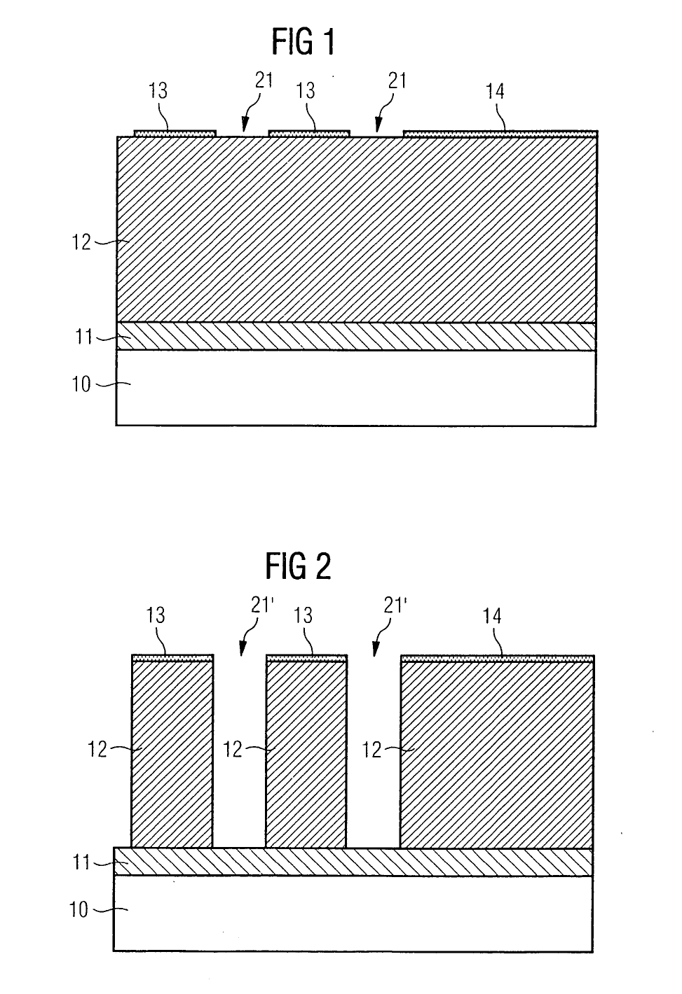

FIGS. 1-6 schematically show the manufacturing process for an acceleration sensor according to a first embodiment of the present invention in a cross-section.

The layer sequence shown in FIG. 1 is a cross-section through the layer structure of a micromechanical component in the form of an acceleration sensor in the area of the movable and fixed electrodes, which are to be structured as a comb structure, for example, from functional layer 12. Layer 10 is the substrate here (the material is Si, SiO₂, for example). Layer 11 is a sacrificial layer (e.g., SiO₂, Si, highly doped Si, phosphosilicate glass). As stated above, layer 12 is used for the functional component structures such as electrode combs in an acceleration sensor (the material is Si, polycrystalline Si, for example). Finally, areas 13 and 14 are parts of one or more structured masking layers (metal, oxide, photoresist, or a multilayer structure made of these components) which, in a subsequent etching step in which the etching attack only occurs in the freely accessible areas 21, are used to define the movable micromechanical structure underneath masking area 13, i.e., the non-movable counterelectrode underneath masking area 14.

After functional layer 12 has been partially covered with masking areas 13 and 14, as shown in FIG. 2, deep trenches 21′ are etched into layer 12 using an anisotropic etching method. For this purpose, any anisotropic etching method that is suitable for layer 12 can be used; however, the fluorine-based deep silicon etching method known from German Patent 42 41 045 is preferred. The etching attack can stop selectively at the boundary with sacrificial layer 11. The etching process can be adjusted so that essentially vertical side walls are obtained as shown in FIG. 2.

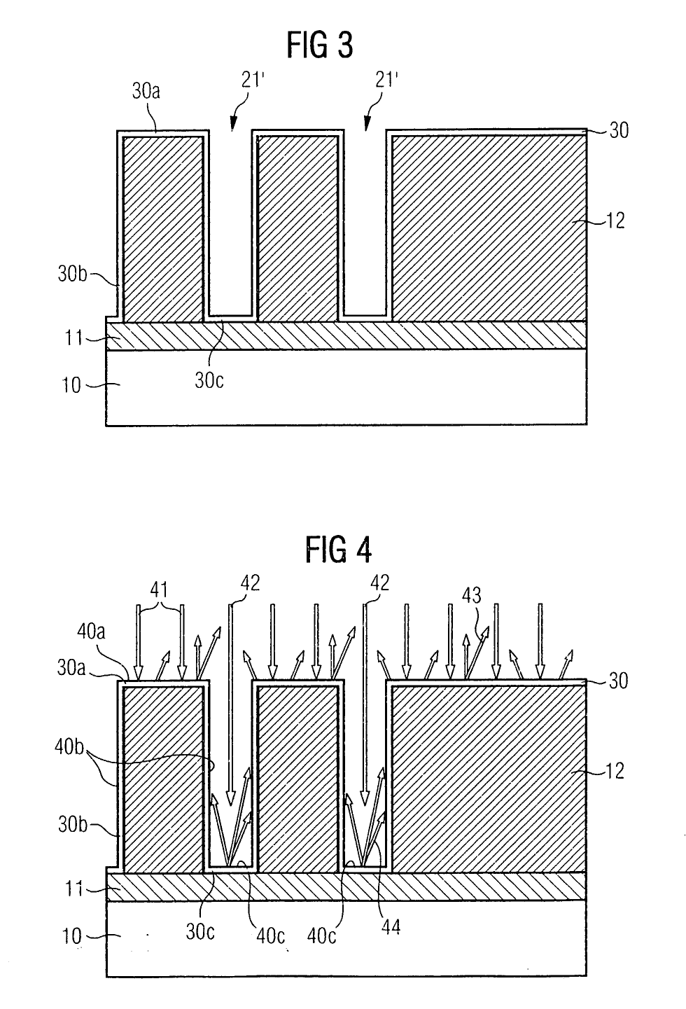

In a subsequent deposition step, which is illustrated in FIG. 3, a conductive material 30 is deposited on the structured surface. Masking areas 13, 14 can be previously removed if so desired.

This conductive material 30 exhibits good adherence to the material of functional layer 12 containing the functional components. This conductive material 30 is preferably a metal; in particular aluminum, AlSi— and AlSiCu-based alloys, nickel, and NiSi alloys are suitable. Metals that produce a low-loss electrical contact with the material of functional layer 12 (for example, polysilicon) are preferably used. Conductive non-metallic compounds such as, for example, ITO (indium-tin oxide) are also suitable. In order to further improve the ohmic contact and metal adherence, it may be necessary to clean the surface of functional layer 12 before the deposition step. Dry and wet chemical processes such as, for example, oxygen ashing or etching with nitric acid- or fluorine-containing etching media are suitable for this purpose.

One important aspect in selecting material 30 and the deposition process is the edge coverage in the area of vertical edges 30b of trenches 21′. Since, according to the present invention, the layer thickness in this area is less than in bare areas 30a on the ditch crest or in areas 30c on the ditch bottom running parallel to the surface, a sufficient amount of material 30 is deposited to achieve a constant and, ideally, homogeneous coverage of the edges. A suitable thickness is between 10 nm and 0.5 μm. Layer 30 can be produced using physical methods such as vapor deposition or sputtering, or using CVD or electrochemical methods.

The following process step is back etching of metal plated areas 30a and 30c on the ditch crests and ditch bottoms, respectively. It is explained with reference to FIG. 4. For this purpose, etching methods that allow anisotropic physical etching, for example, sputtering with heavy particles (argon), are used, directing the plasma in a suitable manner perpendicularly to the wafer surface. Using such an etching method, surfaces 40a and 40c of areas 30a and 30b, respectively, which are parallel to the wafer surface, are etched much more intensively than vertical surfaces of areas 40b. This is due to the maximum transmission of the impulse of accelerated plasma components 41 and 42 hitting these surfaces 40a and 40c perpendicularly. On bare surfaces 40a, the physically etched material is removed isotropically, as indicated by arrows 43.

Thus the layer thickness of area 30a and, occasionally, also masking areas 13, 14 that remain underneath it, is reduced. The layer thickness of surface 40c, running parallel to the surface, in recessed areas 30c is also reduced. However, material 44 removed (etched away) is sputtered against the vertical surfaces 40b of areas 30b and adheres thereto. Thus areas 30a and 30c are back etched, but areas 30b are not etched, i.e. are further plated with metal.

In this step, overetching of metal surface 40c is important, so that sacrificial layer 11 is attacked in depth as FIG. 5 shows.

The back etching process can normally be carried out in the same system as the metal deposition step; however, the plasma is redirected. After back etching, masking layer 13, 14 which may still be present, and optionally part of the material of functional layer 12 in area 50a, is consumed. Areas 50c of sacrificial layer 11 are also etched. Metal film 50b remains on the vertical edges of the component structure.

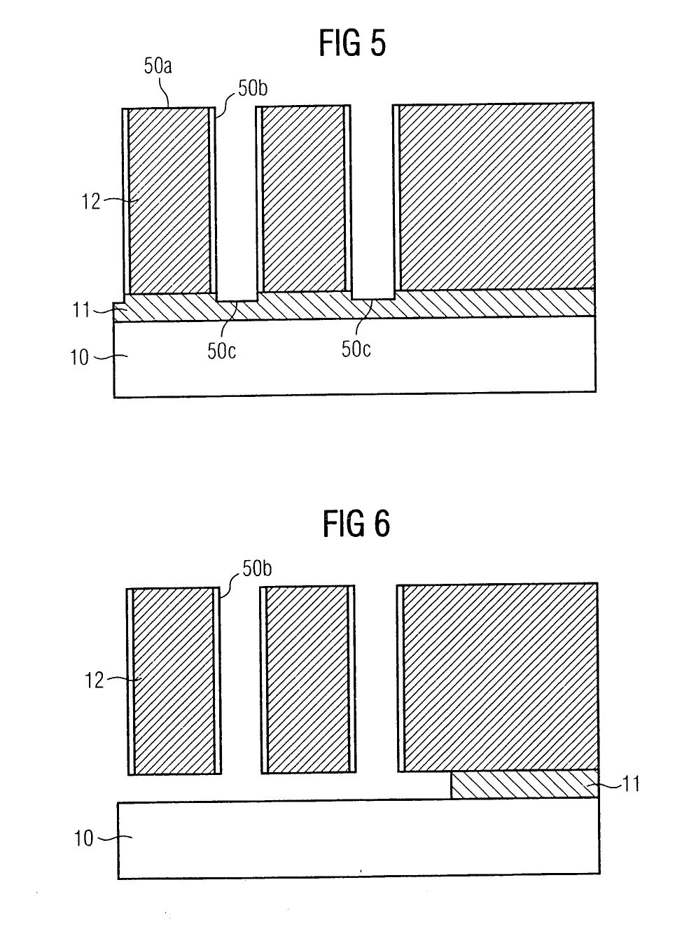

The free, movable component parts are loosened using selective, isotropic etching of sacrificial layer 11 using a suitable method to achieve the state shown in FIG. 6. The etching medium used for removing sacrificial layer 11 does not react too strongly with metal film 50b. In the case of gas phase etching of SiO₂ as sacrificial layer 11 using an HF-containing medium, Al is used for metal plating 50b to form passivating layer AlF₃ if the moisture becomes too high during the etching process. This does not impair the function of metal layer 50b. In order to improve the electrical contact properties between metal layer 50b and the material of functional layer 12, annealing at temperatures above 100° C. in a suitable atmosphere may be used after back sputtering or sacrificial layer etching.

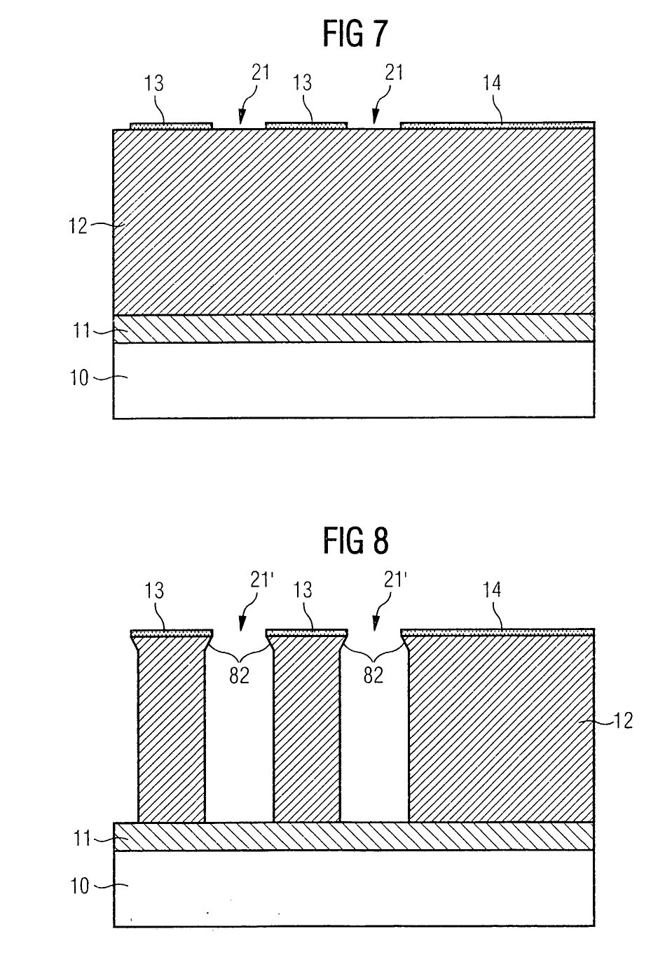

FIGS. 7-11 schematically show the manufacturing process for an acceleration sensor according to a second embodiment of the present invention in a cross-section.

In principle, this second embodiment differs from the first embodiment described in FIGS. 1 to 6 in that the side walls of trenches 21′ of functional layer 12 are not vertical.

The state of the process in FIG. 7 corresponds to that of FIG. 1. According to FIG. 8, the side wall of trenches 21′ of functional layer 12 have a conical shape tapering downward with a projection 82 on the top edge. This can be achieved using a suitable etching process.

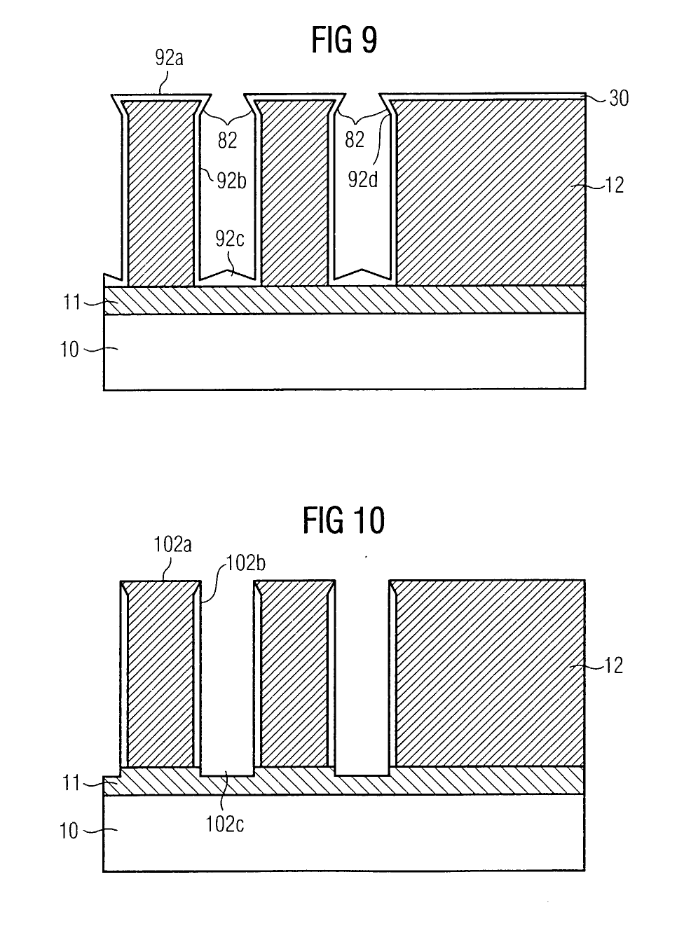

The resulting changes in the metal plating of the side walls are elucidated with reference to FIGS. 9 to 11.

After the deposition of conductive layer 30, the state illustrated in FIG. 9 is obtained. The shading effect of projections 82 with respect to metallic areas 92a-d can be clearly seen.

In this second embodiment, no vertical etching of the side wall metal plating takes place from above when conductive layer 30 is back etched, since projection 82 in the vertical structures of functional layer 12 represents an etching mask, i.e., shading against vertical etching attack. The state after back etching is illustrated in FIG. 10. Metal layer 102b on the side walls runs vertically at the side wall surface and its depth matches the profile of the ditch walls. Area 102c of the sacrificial layer is back etched. Functional layer 12 is bare at surface 102a.

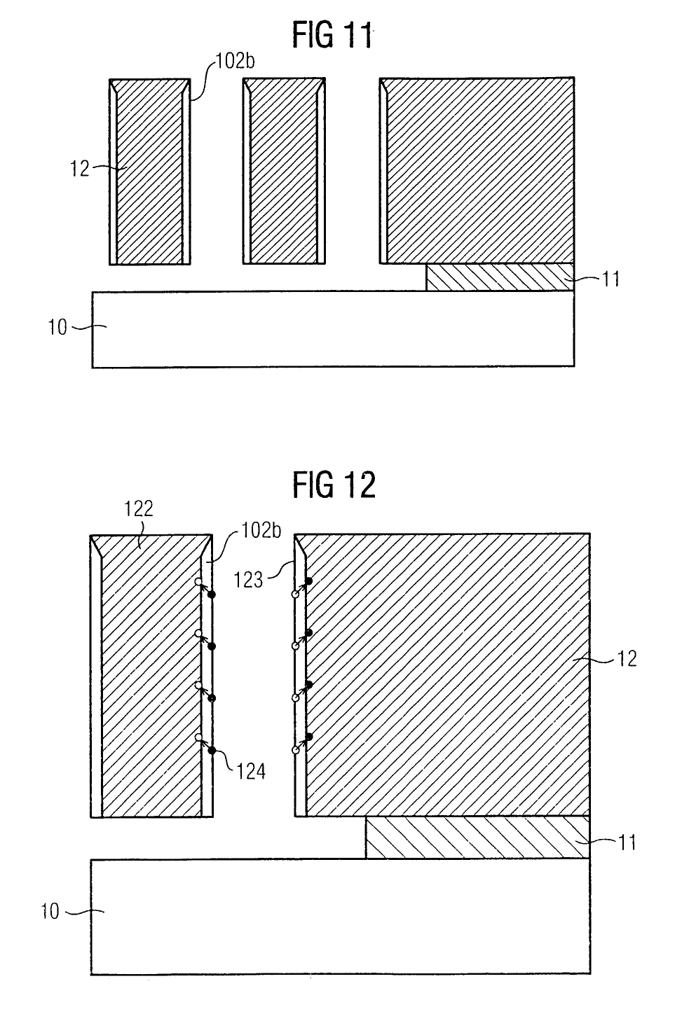

The free, movable component parts are loosened by selective, isotropic etching of sacrificial layer 11 using a suitable method to achieve the state shown in FIG. 11.

FIG. 12 shows a schematic cross-section of the removal and recombination of positive and negative charges 124 on the electrode surfaces, i.e., on conductive film 102b of the side wall metal plating. Recombination is schematically indicated by arrows in this figure. Charges 124 involved may be located inside 122 the semiconductor material of functional layer 12, at the surface of the semiconductor structure, on the insulating layers of the semiconductor surface, or on deposited metal layers 123.

Although the present invention was described above with reference to preferred embodiments, it is not limited thereto, but can be modified in a plurality of ways.

In general, a process similar to the SCREAM method (single crystal reactive etching and metallization) (see also K. A. Shaw, Z. Zhang, N. MacDonald, Sens.& Act. A 40 (1994), 63), SIMPLE-EPI method (Silicon Micromachining by Single Step Plasma Etching) (Y. Li et al., Proc. IEEE MEMS (1995), 398) or BSM-ORMS-method (Black Silicon Method One-run Multi-step) (M. deBoer, H. Jansen, M. Elwenspoek, Proc. Eurosensors IX, Stockholm 1995, 565, 142-C3) is expediently selected.

In contrast to these methods, in side wall metal plating an electrically conductive connection is established between the semiconductor material and the metal film applied. Also, no metal back etching is used in the above-mentioned methods. In methods similar to SCREAM, no separate sacrificial layer such as a sacrificial oxide layer is used.

What is claimed is:

1. A micromechanical component, comprising:
a substrate;
a functional layer;
functional components movably suspended over the substrate in the functional layer, opposite surfaces of the functional components being movable toward one another; and
a conductive film that at least partially coats the opposite surfaces of the functional components.

2. The micromechanical component according to claim 1, wherein:
the micromechanical component corresponds to one of an acceleration sensor and a rotational speed sensor.

3. The micromechanical component according to claim 1, wherein:
the conductive film includes a metal film.

4. The micromechanical component according to claim 3, wherein:
the metal film includes one of aluminum, an alloy based on AlSi and AlSiCu, nickel, and a NiSi alloy.

5. The micromechanical component according to claim 1, wherein:
surfaces of the functional components opposite one another are vertical side walls of trenches.

6. The micromechanical component according to claim 5, wherein:
upper areas of the vertical side walls include projections.

7. The micromechanical component according to claim 1, further comprising:
a sacrificial oxide layer, wherein:
the substrate includes a silicon substrate on which the sacrificial oxide layer is arranged, and
the functional layer includes a polysilicon layer provided on the sacrificial oxide layer.

8. A method of manufacturing a micromechanical component that includes functional components that are movably suspended over a substrate in a functional layer, opposite surfaces of the functional components being movable toward one another, the method comprising the steps of:
preparing the substrate with a sacrificial layer thereon and the functional layer thereon;
forming trenches in the functional layer to define the movably suspended functional components;
conformally depositing a conductive film on an entire surface of a resulting structure;
removing the conductive film in horizontal areas; and
removing some areas of the sacrificial layer to render the movably suspended functional components movable.

9. The method according to claim 8, wherein:
the micromechanical component includes one of an acceleration sensor and a rotational speed sensor

10. The method according to claim 9, further comprising the step of:
etching the trenches into the functional layer so that upper areas of side walls thereof include projections.

11. The method according to claim 10, further comprising the step of:
removing the conductive film in the horizontal areas in accordance with an anisotropic physical etching operation.

12. The method according to claim 11, further comprising the step of:
etching some areas of the sacrificial layer as the conductive film is removed in the horizontal areas.

13. The method according to claim 8, further comprising the step of:
performing an annealing operation to improve electrical contact properties between the functional layer and the conductive film.
